(19) United States
(12) Patent Application Publication
(10) Pub. No.: US 2014/0332185 A1
(43) Pub. Date: Nov. 13, 2014

(54) HEAT INSULATING DEVICE, METHOD FOR MANUFACTURING THE SAME, AND HEAT DISSIPATING SYSTEM INCLUDING THE SAME

(71) Applicant: Wistron Corporation, New Taipei City (TW)

(72) Inventors: Ming-Chih Chen, New Taipei City (TW); Yung-Li Jang, New Taipei City (TW); Wei-Cheng Chou, New Taipei City (TW); Xing-Dong Du, New Taipei City (TW)

(73) Assignee: WISTRON CORPORATION, New Taipei City (TW)

(21) Appl. No.: 14/248,248

(22) Filed: Apr. 8, 2014

(30) Foreign Application Priority Data
May 13, 2013 (CN) 201310175764.X

(51) Int. Cl. H05K 7/20; B23P 15/26; F28D 15/02

(52) U.S. Cl. CPC H05K 7/2039; F28D 15/02; B23P 15/26
USPC 165/104.21; 165/133; 29/890.03

(57) ABSTRACT

A heat dissipating system is disclosed to be disposed in a casing of an electronic apparatus in which a heat source is disposed. The heat dissipating system includes a heat dissipating device and a heat insulating device. The heat dissipating device is in contact with the heat source and has a predetermined heat dissipating path for dissipating heat generated by the heat source. The heat insulating device includes a first layer that is in contact with one of the heat source and the heat dissipating device, and a second layer that is bonded to the first layer and that cooperates with the first layer to define an evacuated space therebetween.

### CROSS REFERENCE TO RELATED APPLICATION

This application claims priority of Chinese Patent Application No. 201310175764.X, filed on May 13, 2013, the disclosure of which is incorporated herein by reference.

### BACKGROUND OF THE DISCLOSURE

1. Field of the Disclosure

The disclosure relates to a heat dissipating system, more particularly to a heat dissipating system with a heat insulating device so that undesirable heat can be dissipated along a predetermined path. This disclosure also relates to a heat insulating device and a method for manufacturing the same.

2. Description of the Related Art

With the continuous creation and development in functions of electronic devices in the information technology industry, performance of chips, such as central processing unit (CPU) or graphic processing unit (GPU), used in the electronic devices, such as laptops, tablet computers, etc., has become ever more powerful. Meanwhile, the size of the electronic devices has become more compact and micronized.

As shown in FIGS. 1 and 2, a conventional electronic device 9 includes a casing 91, a circuit board 92 that is accommodated in the casing 91, a chip unit 93 that is mounted on the circuit board 92 and that generates great heat during operation, and a heat dissipating unit 94 for dissipating the heat generated by the chip unit 93. The heat dissipating unit 94 includes a heat pipe 941 in contact with the chip unit 93 and a fan 942 connected to an end of the heat pipe 941 to transfer the heat out of the casing 91.

Due to micronization of the casing 91, the heat generated by the chip unit 93 during operation or transferred to the heat pipe 91 will be directly transferred to the casing 91. A user tends to be hurt when unintentionally touching the high temperature regions of the casing 91.

### SUMMARY OF THE DISCLOSURE

Therefore, an object of the disclosure is to provide a heat dissipating system that is capable of dissipating heat generated by a heat source which is disposed in a casing of an electronic apparatus along a predetermined heat dissipating path. Thereby, direct conduction of the heat to the casing is avoided.

The heat dissipating system of this disclosure is adapted to be disposed in the casing of the electronic apparatus in which the heat source is disposed and includes a heat dissipating device and a heat insulating device.

The heat dissipating device is in contact with the heat source and has a predetermined heat dissipating path for dissipating heat generated by the heat source.

The heat insulating device includes a first layer that is in contact with one of the heat source and the heat dissipating device, and a second layer that is bonded to the first layer and that cooperates with the first layer to define an evacuated space therebetween. The distance from the second layer to the casing is smaller than that from the first layer to the casing.

Preferably, the heat dissipating device includes a heat pipe and a fan. The heat pipe has a first end that is in contact with the heat source and a second end that is opposite to the first end and that is connected to the fan. The first layer of the heat insulating device is in contact with the first end of the heat pipe.

Preferably, the first layer of the heat insulating device has a profile conforming with that of the one of the heat source and the heat dissipating device so as to enclose the one of the heat source and the heat dissipating device.

Preferably, each of the first and second layers is made of a metallic material.

Another object of this disclosure is to provide a heat insulating device adapted to be incorporated with a heat dissipating device to be disposed in a casing of an electronic apparatus together. The electronic apparatus further includes a heat source disposed in the casing. The heat dissipating device is in contact with the heat source and has a predetermined heat dissipating path for dissipating heat generated by the heat source. Thereby, direct conduction of the heat to the casing is avoided.

The heat insulating device includes a first layer that is in contact with one of the heat source and the heat dissipating device; and a second layer that is bonded to the first layer and that cooperates with the first layer to define an evacuated space therebetween.

Yet another object of this disclosure is to provide a method for manufacturing a heat dissipating system that includes a heat dissipating device and a heat insulating device, including steps of:

dispensing a solder on a surface of one of a first layer and a second layer of the heat insulating device;

soldering the surface of the one of the first layer and the second layer to the other of the first layer and the second layer;

evacuating a closed space defined by and positioned between the soldered first and second layers, thereby completing formation of the heat insulating device; and

connecting the heat insulating device to the heat dissipating device in such a manner that the heat insulating device is disposed on a heat dissipating path of the heat dissipating device.

The effects of this disclosure reside in the use of the heat insulating device in combination with the heat dissipating device to ensure that the heat generated by the heat source is dissipated according to a predetermined heat dissipating path of the heat dissipating device. Conduction of the heat to the space outside of the heat dissipating device can be avoided. Hence, the heat dissipating efficiency of the electronic apparatus using the heat insulating device is enhanced, and the potentially harmful high temperature regions of the casing can be prevented.

### BRIEF DESCRIPTION OF THE DRAWINGS

Other features and advantages of the present disclosure will become apparent in the following detailed description of the embodiment with reference to the accompanying drawings, of which:

FIG. 1 is a fragmentary schematic view for illustrating formation of a high-temperature region on a casing of a conventional electronic device;

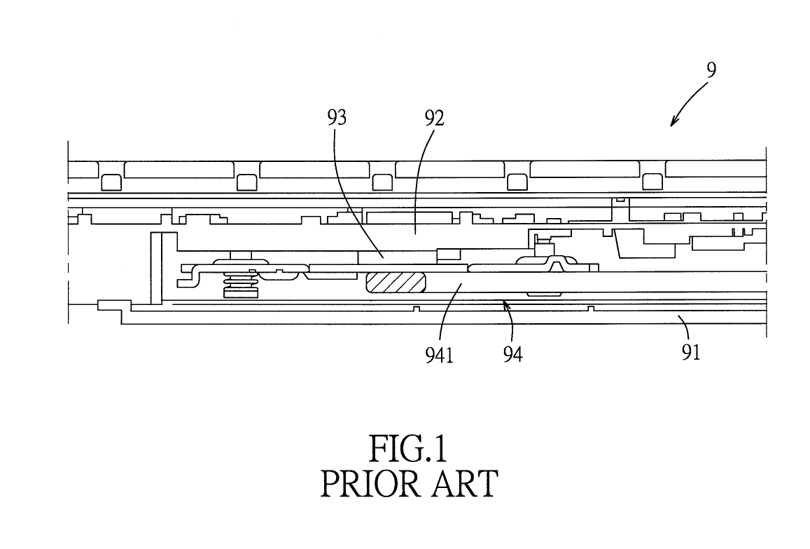

FIG. 2 is a plan view for illustrating placement of a heat dissipating unit and a chip unit of the conventional electronic device;

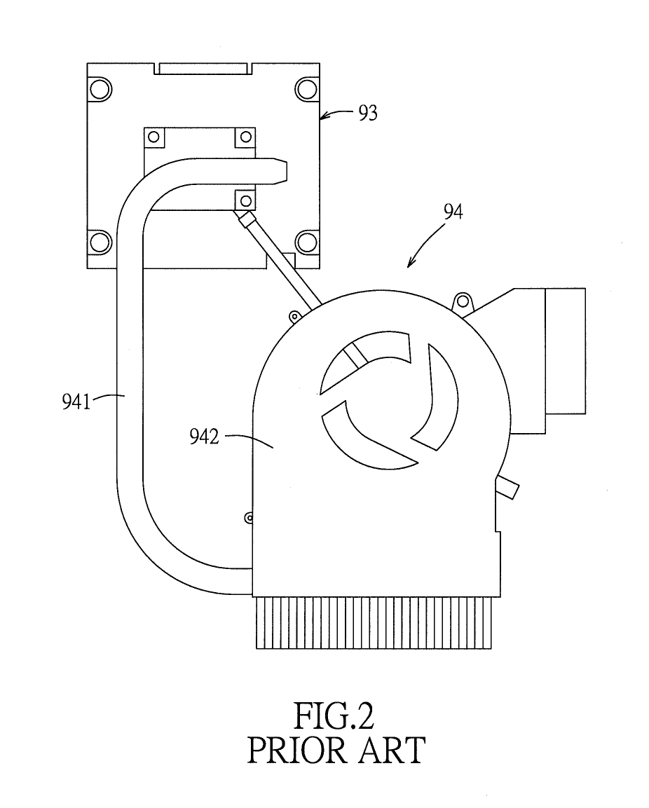

FIG. 3 is an exploded perspective view of the embodiment of a heat dissipating system according to this disclosure;

FIG. 4 is a plan view of the embodiment of the assembled heat dissipating system of this disclosure;

FIG. 5 is a fragmentary sectional view for illustrating how heat conduction between a casing and a high-temperature region within the casing is blocked by the embodiment;

FIG. 6 is a fragmentary schematic view for illustrating a variation of the embodiment of FIG. 5; and

FIG. 7 is a flow chart of a method for manufacturing a heat dissipating system according to this disclosure.

### DETAILED DESCRIPTION OF THE EMBODIMENT

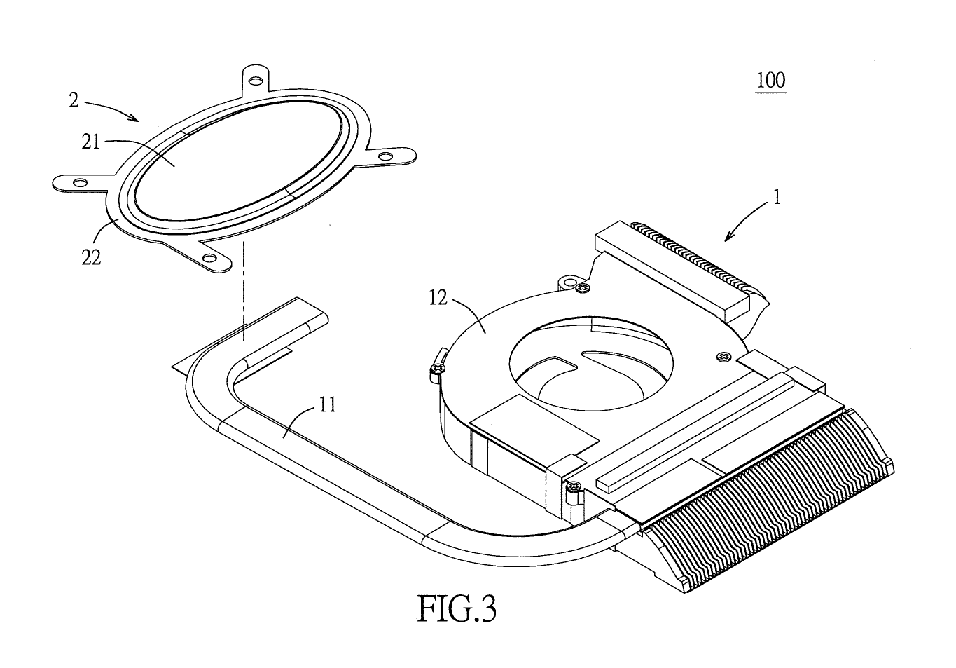

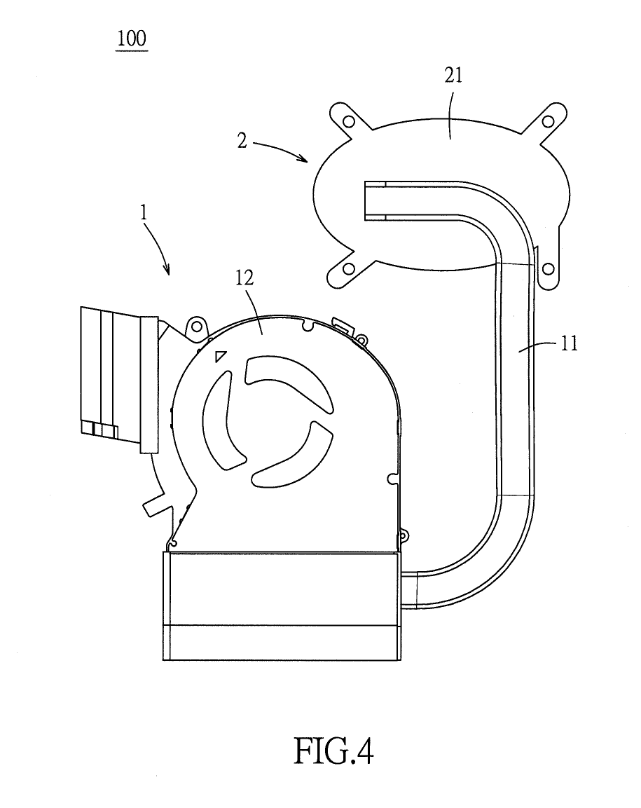

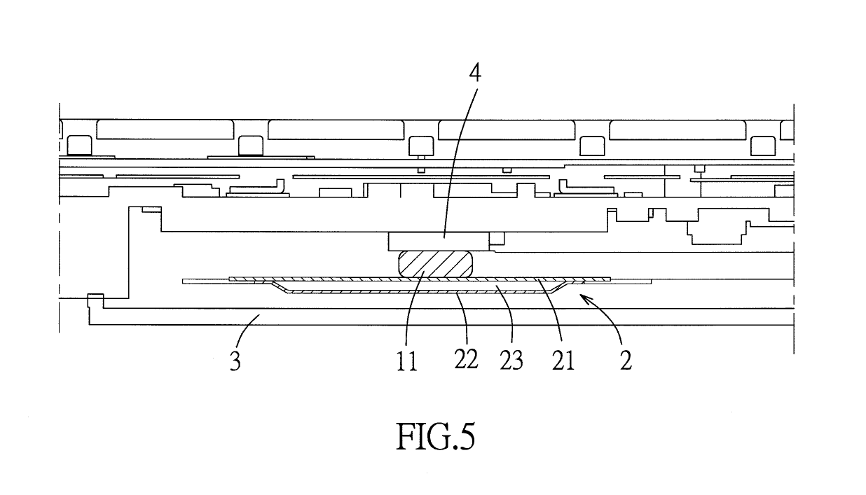

Referring to FIGS. 3, 4 and 5, the embodiment of a heat dissipating system 100 according to this disclosure is shown to be mounted in a casing 3 of an electric apparatus, such as a laptop or a tablet computer. The electronic apparatus further includes a heat source 4, such as CPU, GPU, etc., disposed in the casing 3.

The heat dissipating system 100 of the embodiment includes a heat dissipating device 1 and a heat insulating device 2.

The heat dissipating device 1 includes a heat conducting element 11 and a fan 12. In this embodiment, the heat conducting element 11 is a heat pipe having a first end that is in contact with the heat source 4 and a second end that is opposite to the first end and that is connected to the fan 12, and the fan 12 blows off the heat out of the casing 3. Thereby, a predetermined heat dissipating path of the heat dissipating device 1 is formed. The heat conducting element 11 of the heat dissipating device 1 of this disclosure may have variant types and is not limited to the heat pipe shown in the embodiment, as long as the heat generated by the heat source 4 can be effectively dissipated along the predetermined heat dissipating path.

The heat insulating device 2 of this embodiment is positioned in the predetermined heat dissipating path and includes a first layer 21 and a second layer 22. The first layer 21 is in contact with one of the heat source 4 and the heat dissipating device 1. The second layer 22 is bonded to the first layer 21 and cooperates with the first layer 21 to define an evacuated space 23 therebetween. In this embodiment, the first layer 21 is in contact with the first end of the heat pipe. Preferably, the first and second layers 21, 22 are made of a metallic material. Preferably, the distance from the second layer 22 to the casing 3 is smaller than that from the first layer 21 to the casing 3.

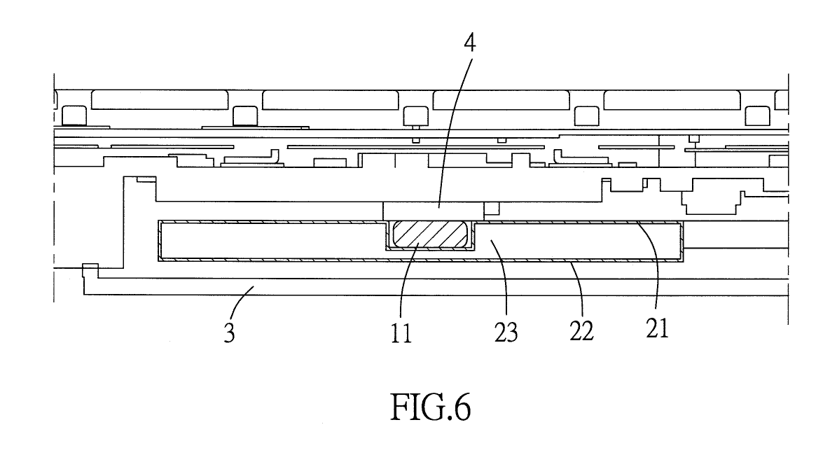

Preferably, as shown in FIG. 6, the first layer 21 of the heat insulating device 2 can be modified to have a profile conforming with that of the one of the heat source 4 and the heat dissipating device 1 so as to enclose the one of the heat source 4 and the heat dissipating device 1. Thereby, the heat generated by the heat source 4 is blocked to be dissipated out through the predetermined heat dissipating path.

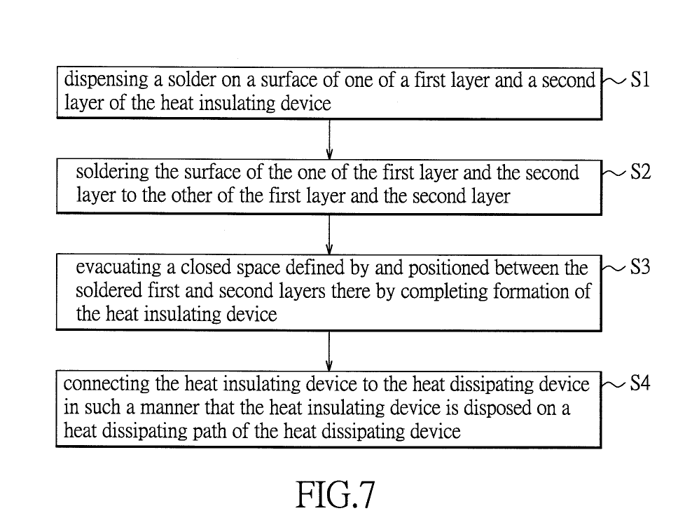

Referring to FIGS. 3, 5 and 7, a method of manufacturing a heat dissipating system having a heat dissipating device and a heat insulating device includes:

step S1 of dispensing a solder on a surface of one of the first layer 21 and the second layer 22 of the heat insulating device 2;

step S2 of soldering the surface of the one of the first layer 21 and the second layer 22 to the other of the first layer 21 and the second layer 22;

step S3 of evacuating the closed space 23 defined by and positioned between the soldered first and second layers 21, 22, thereby completing the formation of the heat insulating device 2; and

step S4 of connecting the heat insulating device 2 to the heat dissipating device 1 in such a manner that the heat insulating device 2 is disposed on a heat dissipating path of the heat dissipating device 1.

It is noted that the abovementioned steps S2 and S3 may be conducted simultaneously in a vacuum environment. Alternatively, step S3 is conducted in a vacuum apparatus after step S2 is completed.

Preferably, before step S3 and after step S2, the soldered first and second layers 21, 22 may be moved to pass through a reflow oven. Since the atmospheric pressure is greater than the pressure inside the closed space 23, the first and second layers 21, 22 cannot be separated from each other and the pores present in the solder can be eliminated during the reflow heating process. Thereby, the bonding strength between the first and second layers 21, 22 is enhanced.

Preferably, in step S4, the heat dissipating device 1 is connected to the heat insulating device 2 by soldering techniques so that the heat insulating device 2 is located between the heat dissipating device 1 and the casing 3.

Moreover, when the size of the heat insulating device 2 is sufficiently large relative to the casing 3 as to be able to cover most of electronic components inside the casing 3, the heat insulating device 2 provides a heat-shielding effect since the first and second layers 21, 22 are made of a metallic material.

In sum, with the provision of the heat dissipating device 1 cooperating with the heat insulating device 2, the heat generated by the heat source 4 is blocked from being dissipated to the space outside the heat dissipating device 1 when encountering the heat insulating device 2 having the evacuated space 23. In such a manner, the heat is concentrated to be dissipated along the predetermined heat dissipating path of the heat dissipating device 1. The heat dissipating efficiency is enhanced and the potentially harmful high temperature region of the casing 3 is eliminated.

While the present disclosure has been described in connection with the embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A heat dissipating system adapted to be disposed in a casing of an electronic apparatus in which a heat source is disposed, said heat dissipating system comprising:
a heat dissipating device in contact with the heat source and having a predetermined heat dissipating path for dissipating heat generated by the heat source; and
a heat insulating device including:
a first layer that is in contact with one of the heat source and said heat dissipating device; and
a second layer that is bonded to said first layer and that cooperates with said first layer to define an evacuated space therebetween, the distance from said second layer to the casing being smaller than that from said first layer to the casing.

2. The heat dissipating system of claim 1, wherein said heat dissipating device includes a heat pipe and a fan, said heat pipe having a first end that is in contact with the heat source and a second end that is opposite to said first end and that is connected to said fan, said first layer of said heat insulating device being in contact with said first end of said heat pipe.

3. The heat dissipating system of claim 1, wherein said first layer of said heat insulating device has a profile conforming with that of the one of the heat source and said heat dissipating device so as to enclose the one of the heat source and said heat dissipating device.

4. The heat dissipating system of claim 1, wherein each of said first and second layers is made of a metallic material.

5. The heat dissipating system of claim 2, wherein said first layer of said heat insulating device has a profile conforming with that of the one of the heat source and said heat dissipating device so as to enclose the one of the heat source and said heat dissipating device.

6. The heat dissipating system of claim 2, wherein each of said first and second layers is made of a metallic material.

7. A heat insulating device adapted to be incorporated with a heat dissipating device to be disposed in a casing of an electronic apparatus together, the electronic apparatus further including a heat source disposed in the casing, the heat dissipating device being in contact with the heat source and having a predetermined heat dissipating path for dissipating heat generated by the heat source, said heat insulating device, comprising:
a first layer that is in contact with one of the heat source and the heat dissipating device; and
a second layer that is bonded to said first layer and that cooperates with said first layer to define an evacuated space therebetween, the distance from said second layer to the casing being smaller than that from said first layer to the casing.

8. The heat insulating device of claim 7, wherein said first layer of said heat insulating device has a profile conforming with that of the one of the heat source and the heat dissipating device so as to enclose the one of the heat source and the heat dissipating device.

9. The heat insulating device of claim 7, wherein each of said first and second layers is made of a metallic material.

10. The heat insulating device of claim 8, wherein each of said first and second layers is made of a metallic material.

11. A method for manufacturing a heat dissipating system that includes a heat dissipating device and a heat insulating device, comprising:
dispensing a solder on a surface of one of a first layer and a second layer of the heat insulating device;
soldering the surface of the one of the first layer and the second layer to the other of the first layer and the second layer;
evacuating a closed space defined by and positioned between the soldered first and second layers, thereby completing formation of the heat insulating device; and
connecting the heat insulating device thus formed to the heat dissipating device in such a manner that the heat insulating device is disposed on a heat dissipating path of the heat dissipating device.

12. The method of claim 11, wherein soldering of the surface of the one of the first and second layers to the other of the first and second layers and evacuating of the closed space are conducted simultaneously in a vacuum environment.

13. The method of claim 11, wherein evacuating of the closed space is conducted in a vacuum apparatus after soldering of the surface of the one of the first and second layers to the other of the first and second layers is completed.
